(19) United States
(12) Patent Application Publication
(10) Pub. No.: US 2018/0053681 A1
(43) Pub. Date: Feb. 22, 2018

(54) A COMPONENT HANDLING ASSEMBLY

(71) Applicant: Rasco GMBH, Kolbermoor (DE)

(72) Inventors: Rainer HITTMANN, Grosskarolinenfeld (DE); Max SCHAULE, Mindelheim (DE); Dieter SCHMID, Bruckmühl (DE)

(21) Appl. No.: 15/556,835

(22) PCT Filed: May 29, 2015
(86) PCT No.: PCT/EP2015/061990

§ 371 Date: Sep. 8, 2017

(51) Int. Cl. H01L 21/683; H05K 13/04

(52) U.S. Cl. CPC H01L 21/6838; B65G 47/917; H05K 13/0408

(57) ABSTRACT

According to the present invention there is provided a component handling assembly ( ) suitable for facilitating loading or unloading a plurality of components onto/from a carrier, the assembly comprising, a carrier (1) which comprises a surface (3) on which a plurality of components (50) can be supported, wherein the surface (3) has a plurality of holes (5) defined therein; a vacuum generator (21) which can be arranged in fluid communication with said plurality of holes (5) in the surface (3) of the carrier (1) so that a vacuum can be applied, through said plurality of holes (5), to components (50) supported on the surface (3) of the carrier (1), to hold components (50) on the surface (3) of the carrier (5); a vacuum sensor (22) for sensing the level of vacuum applied to components (50) supported on the surface (3) of the carrier; a controller (23) for controlling the vacuum generator (21) during loading and/or unloading of component(s) onto/from the surface (3) of the carrier, based on the level of vacuum sensed by the vacuum sensor (22), so that a predefined level of vacuum is applied to component(s) (50) supported on the surface (3) during loading and/or unloading of component(s) (50) onto/from the carrier (1). There is further provided a corresponding method of handling components (50).

### FIELD OF THE INVENTION

The present invention relates to a component handling assembly, and in particular to a component handling assembly in which the level of vacuum applied to components supported on the surface of a carrier, to hold the components on said surface, remains substantially constant as additional components are loaded onto the surface and/or remains substantially constant as additional components are unloaded from the surface.

### BACKGROUND

Typically in existing component handling assemblies components are held on a carrier by mechanical means. In other component handling assemblies the components are held on a carrier by means of a vacuum; in such cases the surface of the carrier comprises holes (vacuum holes) and a vacuum is applied through these holes to components which are supported on the surface of the carrier; the vacuum force holds the components on the surface of the carrier.

When a component is placed on the surface of the carrier it will cover one or more of the vacuum holes thus restricting, or completely blocking, fluid flow through those one or more vacuum holes (i.e. the component will substantially ‘close’ those one or more vacuum holes which is covers). Disadvantageously, as an increasing number of components are loaded onto the surface of the carrier the amount of vacuum force which is experienced by each of components on the surface increases, because an increasing number of vacuum holes are being closed by components which are added to the surface. The increased vacuum force experienced by each components on the surface of the carrier hinders the picking of the components from the carrier, or at least necessitates the use of a mechanical aid (such as a needle) to help pick the components from the surface of the carrier—or switch off the vacuum completely. For example if the components are to be picked by a component handling head which is designed to hold components by means of a vacuum, then the vacuum force experienced by each components on the surface of the carrier may exceed the vacuum applied to the component by the component handling head thus preventing the component handling head from being able to pick the components, unaided, from the surface of the carrier.

Likewise when unloading components from the surface of the carrier, as components are picked from the surface then an increasing number of the vacuum holes which were previously covered by components, now become uncovered (i.e. ‘open’) thus allowing fluid flow through those vacuum holes. Disadvantageously, as an increasing number of components are picked from the surface of the carrier the amount of vacuum force which is experienced by each of the components remaining on the surface decreases, because fluid can flow through an increasing number of vacuum holes. The vacuum force may decrease such that the vacuum force is insufficient to reliably hold the remaining components on the surface of the carrier; thus there is an increased risk of components becoming displaced during picking of components from the carrier.

Furthermore, if the surface of the carrier is only sparsely populated with components (i.e. if only a few components are supported on the surface of the carrier) this will leave a large number of the vacuum holes uncovered and thus ‘open’. Much of the vacuum may escape through the uncovered vacuum holes, consequently, the amount of vacuum force experienced by each component on the surface of the carrier will be reduced and may be insufficient to hold those components on the surface of the carrier as the carrier moves. Thus if the carrier is only sparsely populated with components then there is an increased risk that the components may become displaced during transport of the carrier due to acceleration forces.

It is an aim of the present invention to obviate or mitigate at least some of the disadvantages associated with the existing solutions in the field.

### SUMMARY OF THE INVENTION

According to the present invention there is provided component handling assembly suitable for facilitating loading or unloading a plurality of components onto/from a carrier, the assembly comprising, a carrier which comprises a surface on which a plurality of components can be supported, wherein the surface has a plurality of holes defined therein; a vacuum generator which can be arranged in fluid communication with said plurality of holes in the surface of the carrier so that a vacuum can be applied, through said plurality of holes, to components supported on the surface of the carrier, to hold components on the surface of the carrier; a vacuum sensor for sensing the level of vacuum applied to components supported on the surface of the carrier; a controller for controlling the vacuum generator during loading and/or unloading of component(s) onto/from the surface of the carrier, based on the vacuum sensed by the vacuum sensor, so that a predefined level of vacuum is applied to component(s) supported on the surface during loading and/or unloading of component(s) onto/from the carrier.

It will be understood that the carrier includes any structure which can be used to transport components. The carrier may take any suitable configuration. For example the carrier may comprise a boat and/or the carrier may comprise an x-y table.

It should be understood that the component(s) may take any suitable shape, design or configuration. Preferably the component(s) are electronic component(s).

One of the advantages of the assembly of the present invention is that the vacuum level experienced by components on the carrier can be maintained at a predefined level regardless of the number of components which are loaded or unloaded from the carrier.

As more components are loaded (placed) on the surface of the carrier an increasing number of holes on the surface of the carrier will become covered, thus become ‘closed’, by the components which are placed; to ensure that the amount of vacuum applied to components on the surface does not increase beyond the predefined level of vacuum, the controller will thus control the vacuum generator to decrease the vacuum generated by the vacuum generator so that the level of vacuum applied to the components on the surface of the carrier is maintained at the predefined level as additional components are loaded onto the surface of the carrier.

Likewise the present invention offers advantages when unloading (picking) components from the carrier; when components are picked an increasing number of the vacuum holes, which were previously covered by components, become uncovered and thus ‘open’ through which the vacuum can escape. In order to prevent the amount of vacuum applied to components remaining on the surface from decreasing, the controller will thus control the vacuum generator to increase the vacuum generated by the vacuum generator so that the level of vacuum applied to the components remaining on the surface of the carrier is maintained at the predefined level as additional components are unloaded from the surface of the carrier.

The present invention further offers the advantage of allowing components to be picked from the carrier using exclusively a handling head which is designed to hold a component using a vacuum: the controller can control the vacuum generator so that the vacuum force experienced by components on the surface of the carrier is less than the level of vacuum applied to the components by a component handling head which is used to unload a component from the carrier. Accordingly the components can be unloaded from the carrier using the component handling heads exclusively, without any need for mechanical aids (e.g. a needle which is used to help lift the component from the surface of the carrier during picking).

Preferably the predefined level of vacuum is a constant vacuum level (i.e. a single vacuum level). For example the predefined level of vacuum may be a level of vacuum between −30-50 kPa.

In an embodiment a single predefined level of vacuum is applied to components supported on the surface during the loading and unloading of components from the carrier. In other words the controller controls the vacuum generator so that the predefined level of vacuum which is applied to components supported on the surface during the loading of components onto the carrier is the same as the predefined level of vacuum which is applied to components on the surface of the carrier during the unloading of components from the carrier. For example the single predefined level of vacuum may be 40 kPa so that a vacuum level of 40 kPa is applied to components on the surface of the carrier when loading components onto the surface of the carrier, and a vacuum level of 40 kPa is applied to components on the surface of the carrier when unloading components from the surface of the carrier.

In another embodiment a first constant predefined level of vacuum may be defined for when loading components onto the carrier, and a second constant predefined level of vacuum may be defined for when unloading components from the carrier. For example a first predefined level of vacuum may be applied to components on the surface of the carrier when loading components onto the surface of the carrier and a second predefined level of vacuum force may be applied to components on the surface of the carrier when unloading components from the surface of the carrier.

Preferably the first predefined level of vacuum will be larger than the second predefined level of vacuum. For example the first predefined level of vacuum may be 50 kPa, the second predefined level of vacuum may be 30 kPa. In another embodiment the first predefined level of vacuum will be equal to the second predefined level of vacuum.

A third constant predefined level of vacuum may be defined for when consecutively alternating between unloading a single component from the surface of the carrier and loading a single component onto the surface of the carrier.

Preferably the third predefined level of vacuum will be less than the first predefined level of vacuum and will be larger than the second predefined level of vacuum. For example the third predefined level of vacuum may be 40 kPa. In another embodiment the first, second and third predefined levels of vacuum will be equal to each other.

If, for example, the carrier is to be consecutively loaded with a plurality of components, then the controller may control the vacuum generator so that a substantially constant first predefined level of vacuum of 50 kPa is applied to components on the surface of the carrier. As an increasing number of components are loaded onto the carrier the number of holes in the surface of the carrier which are covered (i.e. closed) by components will increase; thus as an increasing number of components are loaded onto the surface of the carrier the controller will control the vacuum generator so that it generates an decreasingly lower vacuum so that a substantially constant level of vacuum of 50 kPa is applied to components on the surface of the carrier as an increasing number of components are loaded onto the surface of the carrier.

Similarly, if for example, components are to be unloaded from the surface of the carrier, then the controller may control the vacuum generator so that a substantially constant second predefined level of vacuum of 30 kPa is applied to components on the surface of the carrier. As an increasing number of components are unloaded from the carrier an increasing number of holes in the surface of the carrier will be uncovered (i.e. closed); thus as an increasing number of components are unloaded from the surface of the carrier the controller will control the vacuum generator so that it generates an increasingly higher vacuum so that a substantially constant level of vacuum of 30 kPa is applied to components on the surface of the carrier as an increasing number of components are unloaded from the surface of the carrier.

Similarly, if for example, single components are to be consecutively alternately unloaded and loaded from/onto the surface of the carrier then the controller will control the vacuum generator so that a substantially constant third predefined level of vacuum of 40 kPa is applied as components on the surface of the carrier.

The controller may be configured to control the vacuum generated by the vacuum generator, based on the vacuum level sensed by the vacuum sensor, so that, a first predefined level of vacuum applied to components supported on the surface during loading of components onto the surface of the carrier; and so that a second predefined level of vacuum force is applied to components supported on the surface during unloading components from the surface of the carrier.

The controller may be configured to control the vacuum level generated by the vacuum generator, based on the vacuum sensed by the vacuum sensor, so that, a first predefined level of vacuum is applied to components supported on the surface during exclusive loading of components onto the surface of the carrier; and so that a second predefined level of vacuum is applied to components supported on the surface during exclusive unloading components from the surface of the carrier. In the present application ‘exclusive loading of components’ means loading a plurality of components, consecutively, onto the surface of the carrier without unloading any components from the surface between consecutive loading of the plurality of components; ‘exclusive unloading of components’ means unloading a plurality of components, consecutively, from the surface of the carrier without loading any components on the surface between consecutive unloading of the plurality of components.

In an embodiment the controller comprises a closed loop control system which enables it to control the vacuum generated by the vacuum generator based on the vacuum sensed by the vacuum sensor.

The controller may be configured to decrease the vacuum generated by the vacuum generator when components are being loaded onto the surface of the carrier, so that a substantially constant first predefined level of vacuum is applied to components supported on the surface as additional components are loaded onto the surface of the carrier.

The controller may be configured to increase the vacuum generated by the vacuum generator as components are being unloaded from the surface of the carrier, so that a substantially constant second predefined level of vacuum is applied to components remaining supported on the surface as components are unloaded from the surface of the carrier.

The vacuum generator may comprise, a venturi, an output of which is fluidly connected to the holes on the surface of the carrier; an air supply; and a proportional valve, which is arranged such that it can receive air from the air supply and can input received air into the venturi, wherein the proportional valve is operable to control the pressure and flow of air which is input to the venturi; and the controller may be configured to control the vacuum generator so that a predefined level of vacuum is applied to components on the carrier, by operating the proportional valve to increase the pressure and flow of air input to the venturi to achieve an increase in the vacuum generated by the vacuum generator and/or to decrease the pressure of the air input to the venturi to achieve a decrease in the vacuum generated by the vacuum generating means.

Preferably the venturi is configured to generate a vacuum at its output which is proportional to the pressure of the air which is input to the venturi. Most preferably the venturi is configured to generate a vacuum at its output which is directly proportional to the pressure of the air which is input to the venturi. Thus inputting air with increased pressure into the venturi effects an increase in the vacuum generated at the output of the venturi and thus effects an increase in the vacuum experienced by components on the surface of the carrier. Similarly inputting air with decreased pressure into the venturi effects a decrease in the vacuum generated at the output of the venturi and thus effects a decrease in the vacuum experienced by components on the surface of the carrier.

Thus controller is configured to decrease the vacuum generated by the vacuum generator when components are loaded onto the surface of the carrier by operating the proportional valve to decrease the pressure of air input to the venturi, so that a substantially constant predefined level of vacuum is applied to components supported on the surface as additional components are loaded onto the surface of the carrier.

Similarly the controller is configured to increase the vacuum generated by the vacuum generator when components are being unloaded from the surface of the carrier by operating the proportional valve to increase the pressure of air input to the venturi, so that a substantially constant predefined level of vacuum is applied to components remaining on the surface of the carrier as additional components are unloaded from the surface of the carrier.

The assembly may further comprise a conduit which is fluidly connected to an output the vacuum generator, and wherein the vacuum sensor is located within the conduit. Preferably the vacuum sensor is located within the conduit proximate to an end of the conduit which is opposite to the end which is connected to the vacuum generator.

The assembly may further comprise one or more component handling heads which can be used to unload components from the surface of a carrier, and wherein each of the one or more component handling heads is configured to hold a component by means of a vacuum, and, wherein the second predefined level of vacuum is less than the vacuum used to hold the a component on a component handling head, so that the components can be unloaded directly from the carrier using the one or more component handling heads exclusively.

The assembly may further comprise one or more component handling heads which can be used to load components from the surface of a carrier, and wherein each of the one or more component handling heads is configured to hold a component by means of a vacuum, and, wherein the first predefined level of vacuum is greater than the vacuum used to hold the a component on a component handling head, so as to facilitate the transfer of components from the component handling heads to the surface of the carrier.

The one or more component handling heads may be provided on a rotatable turret.

The assembly may comprise a means for selecting a map, from a plurality of predefined maps, showing locations on the surface of the carrier which components are to occupy when placed, and a means for moving the carrier relative to the component handling heads on the turret so that consecutive component handling heads can place the components on the surface of the carrier at the locations shown in the selected map.

The assembly may further comprise a means for aligning a component to a predefined orientation, while the component is held by the component handling head. Preferably the assembly further comprise a means for aligning a component to a predefined orientation, while the component is held by the component handling head prior to placing the component on the surface of the carrier.

The carrier may further comprise a single vacuum chamber which is fluidly connected to the plurality of holes on the surface of the carrier.

The vacuum sensor may be located in the single vacuum chamber of the carrier.

The single vacuum chamber may be fluidly connected to an inlet of the carrier which can be fluidly connected to a vacuum generator. The vacuum sensor may be located in the first inlet of the carrier.

Preferably the single vacuum chamber may be selectively fluidly connected with vacuum generator.

The single vacuum chamber may be selectively fluidly connected with a conduit which is connected to an output of the venturi. The vacuum sensor may be located in the conduit. Preferably the vacuum sensor may be located at an end portion of the conduit which is opposite to the end which connected to an output of the venturi.

The carrier may further comprise an inlet which is fluidly connected to the plurality of holes on the surface of the carrier and can be fluidly connected to a vacuum generator. The vacuum sensor may be located in the inlet of the carrier.

The carrier may further comprise a second inlet which can be selectively fluidly connected to another, second, vacuum generating means, simultaneously when the first inlet is connected to the vacuum generating means. The other second inlet is configured to be in fluid communication with the same holes on the surface of the carrier as the holes which the first inlet is in fluid communication with.

According to a further aspect of the present invention there is provided a method of loading or unloading components from a surface of a carrier, the method comprising the steps of, receiving into a loading or unloading area, a carrier which comprises surface on which the plurality of components can be supported, wherein the surface has a plurality of holes defined therein; using a vacuum generator to provide a vacuum through said plurality of holes, which can be applied, through said plurality of holes, to components supported on the surface of the carrier; using a vacuum sensor to sense the level of vacuum applied to component(s) supported on the surface of the carrier; using a controller to control the vacuum generator during loading and/or unloading of component(s) onto/from the surface of the carrier, based on the level of vacuum sensed by the vacuum sensor, so that a predefined vacuum force is applied component(s) supported on the surface during loading and/or unloading component(s) onto/from the surface of the carrier.

The method may comprise the step(s) of, controlling the vacuum generated by the vacuum generating means, based on the level of vacuum sensed by the vacuum sensor, so that a first predefined level of vacuum is applied to components supported on the surface during loading of components onto the surface of the carrier; and/or controlling the vacuum generated by the vacuum generating means, based on the level of vacuum sensed by the vacuum sensor, so that a second predefined level of vacuum is applied to components supported on the surface during exclusive unloading of components from the surface of the carrier.

The method may comprise the step of controlling the vacuum generated by the vacuum generating means, based on the level of vacuum sensed by the vacuum sensor, so that a third predefined level of vacuum is applied to components supported on the surface during consecutively, alternately unloading and loading single component from/onto the surface of the carrier.

The method may comprise the step of selecting a constant first predefined level of vacuum, which is to be applied to components on the surface of the carrier when loading components onto the surface of the carrier, which is greater than the level of vacuum which a component handling head in the assembly applies to a component to hold that component.

The method may comprise the step of selecting a constant second predefined level of vacuum, which is to be applied to components on the surface of the carrier when unloading components from the surface of the carrier, which is less than the level of vacuum which a component handling head in the assembly applies to a component to hold that component.

This will ensure that components supported on the surface of a carrier, experience a first, constant, vacuum force during consecutive loading of a plurality of components onto the surface of the carrier; and that components supported on the surface experience a second, constant, vacuum force during consecutive unloading of a plurality of components from the surface of the carrier.

The method may comprise the step of selecting a constant second predefined level of vacuum, which is to be applied to components on the surface of the carrier when consecutively, alternately unloading and loading single component from/onto the surface of the carrier. This will ensure that components supported on the surface of a carrier will experience a third, constant, vacuum during consecutively, alternately unloading and loading single component from/onto the surface of the carrier.

The method may comprise the step of selecting a constant third predefined level of vacuum, based on a minimum force required to hold a component on the surface of the carrier, and the level of vacuum which a component handling head in the assembly applies to a component to hold that component. Preferably the third predefined level of vacuum is selected to be less than the level of vacuum which a component handling head in the assembly applies to a component to hold that component but greater than the minimum force required to hold a component on the surface of the carrier. This will ensure that the components supported on the surface of the carrier experience a third, constant, vacuum force during simultaneous loading and unloading of a plurality of components onto/from the surface of the carrier.

Preferably the second predefined level of vacuum will be less than the first predefined level of vacuum. Preferably the third predefined level of vacuum will be less than the first predefined level of vacuum but greater than the second predefined level of vacuum.

A method may comprise the step of, decreasing the vacuum generated by the vacuum generator when a component is loaded onto the surface of the carrier, so that said predefined level of vacuum is applied, substantially constantly, to components supported on the surface as additional components are placed onto the surface of the carrier.

A method may comprises the step of increasing the vacuum generated by the vacuum generator when a component is unloaded from the surface of the carrier, so that said predefined level of vacuum is applied, substantially constantly, to components remaining supported on the surface of the carrier.

The controller will preferably control the vacuum generator to increase and/or decrease the vacuum generated.

The method may further comprise the step of, controlling the vacuum generator so that level of vacuum applied to components supported on the surface when unloading components from the carrier is less than a level of vacuum applied to a component a by a component handling head which is used to unload a component from the carrier, so that components can be unloaded directly from the carrier using the component handling head exclusively.

The method may further comprise the step of,

controlling the vacuum generator so that level of vacuum applied to components supported on the surface when loading components onto the carrier is greater than a level of vacuum applied to a component by a component handling head which is used to load a component onto the surface of the carrier, so that components can be loaded onto the carrier using the component handling head exclusively.

The vacuum generator may comprise, a venturi, an output of which is fluidly connected to the holes on the surface of the carrier; an air supply; and a proportional valve, which is arranged such that it can receive air from the air supply and can input received air into the venturi, wherein the proportional valve is operable to control the pressure of air which is input to the venturi; and the step of using a controller to control the vacuum generator so that a predefined level of vacuum is applied to components on the carrier comprises, using the controller to operate the proportional valve to increase the pressure of air input to the venturi to achieve an increase in the vacuum generated by the vacuum generator and/or using the controller to operate the proportional valve to decrease the pressure of the air input to the venturi to achieve a decrease in the vacuum generated by the vacuum generating means.

The carrier may comprise a single vacuum chamber which is fluidly connected to said holes defined on the surface of the carrier; and the method may comprise the step of, fluidly connecting the single vacuum chamber to said vacuum generator so that a vacuum can be applied to components on the surface of the carrier.

The step of using a vacuum sensor to sense the level of vacuum applied to components supported on the surface, may comprise measuring the level of vacuum in the single vacuum chamber using a vacuum sensor which is located in the single vacuum chamber.

The carrier may comprise an inlet which is fluidly connected to said holes defined on the surface of the carrier; and the method may comprise the step of, fluidly connecting the inlet to said vacuum generator so that a vacuum force can be applied to components on the surface of the carrier.

The step of using a vacuum sensor to sense the level of vacuum applied to components supported on the surface, may comprise measuring the level of vacuum in the first inlet using a vacuum sensor which is located in the first inlet.

The carrier may comprise a second inlet which is configured to be in fluid communication with the same holes on the surface of the carrier as the holes which the first inlet is in fluid communication with, and the method may comprise the step of, fluidly connecting the second inlet to a second vacuum generator while the first inlet is fluidly connected to said vacuum generating means, so that the first inlet and second inlet are simultaneously connected to respective vacuum generating means.

The assembly may comprise a conduit which is fluidly connected to an output of the vacuum generator. The method may comprise the step of arranging the carrier so that the conduit is fluidly connected with the holes. The step of using a vacuum sensor to sense the level of vacuum applied to components supported on the surface, may comprise measuring the level of vacuum in the conduit using a vacuum sensor which is located in the conduit.

Preferably the carrier is arranged in the receiving area so that the first inlet mechanically cooperates with the conduit so that the vacuum generator is in fluid communication with the holes on the surface of the carrier.

The first inlet may selectively mechanically cooperate with a conduit which is in fluid communication with the vacuum generating means, so as to allow fluid communication between the vacuum generator and the holes on the surface of the carrier; and wherein the step of using a vacuum sensor to sense the level of vacuum applied to components supported on the surface, comprises measuring the vacuum in the conduit using a vacuum sensor which is located in the conduit.

According to a further aspect of the present invention there is provided a system suitable for use when loading or unloading a plurality of components onto/from a carrier, the system comprising, a receiving area which is configured such that it can receive a carrier which comprises surface on which a plurality of components can be supported, wherein the surface has a plurality of holes defined therein; a vacuum generator which, when a carrier is received into the loading area, can be arranged in fluid communication with said plurality of holes so that a vacuum can be applied through said plurality of holes to hold components which are on the surface of the carrier; a vacuum sensor which can sense the level of vacuum applied to components supported on the surface of the carrier; a controller for controlling the vacuum generated by the vacuum generator, based on the level of vacuum sensed by the vacuum sensor, so that a predefined level of vacuum is applied to components supported on the surface during loading and/or unloading components onto/from the carrier.

The system may have any one or more of the features of the above-mentioned assembly.

### BRIEF DESCRIPTION OF DRAWINGS

The invention will be better understood with the aid of the description of an embodiment given by way of example and illustrated by the figures, in which:

FIG. 1 shows a cross sectional view of an exemplary carrier which can be used in the a component handling assembly according to the present invention;

FIG. 2 provides a perspective view of a component handling assembly according to an exemplary embodiment of the present invention;

FIG. 3 is a block diagram illustrating the features of vacuum generating means;

FIGS. 4 & 5 illustrates different locations within the component handling assembly in which the vacuum sensor can be positioned.

### DETAILED DESCRIPTION

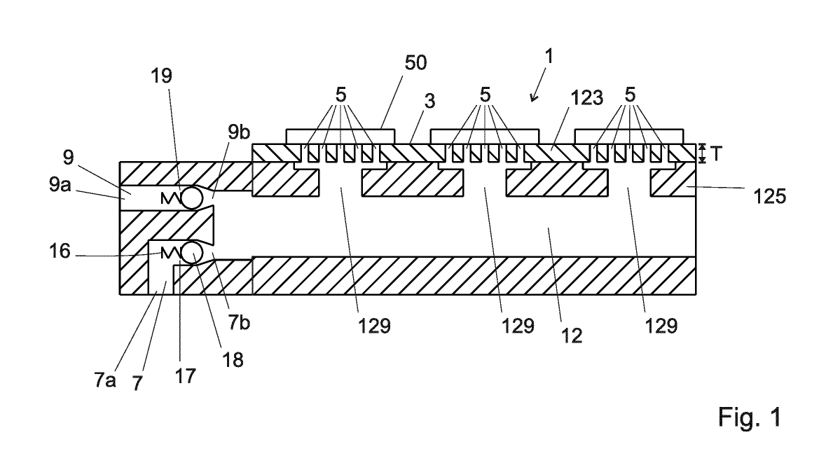

FIG. 1 provides a simplified longitudinal section view of part of the exemplary carrier 1 which can be used in component handling assembly according to an embodiment of the present invention. In this example the carrier 1 is in the form of a boat 1. The carrier 1 comprises a surface 3 on which a plurality of components 50 have been loaded. The surface 3 has a plurality holes 5 defined therein through which a vacuum can pass to hold the components 50 on the surface 3.

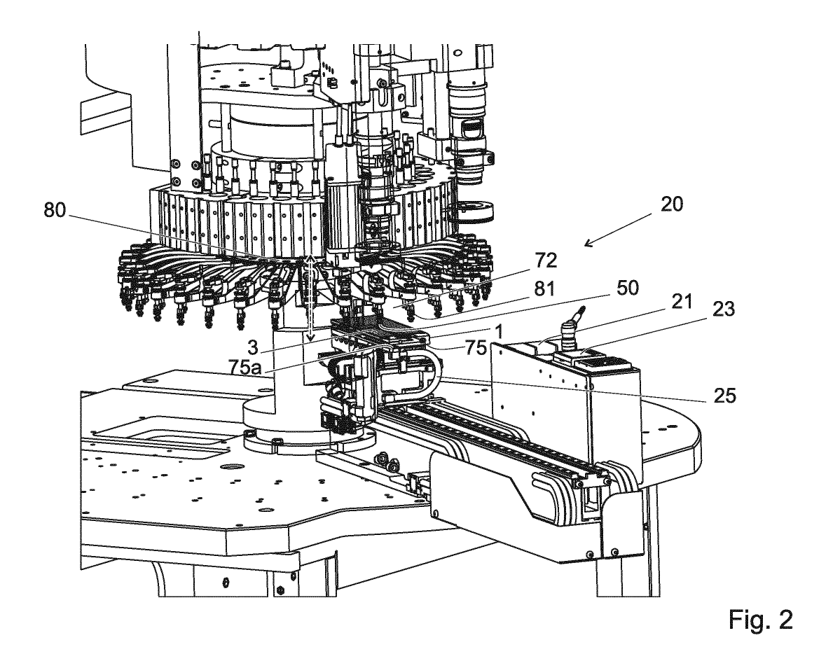

In this exemplary embodiment shown in FIG. 2 the surface 3 is defined by a metal layer 123. Preferably metal layer 123 has a thickness ‘T’ of between 0.3 mm-2 mm; and preferably the metal layer 123 comprises sheet metal. The metal layer 23 may comprise any suitable material such as aluminium alloys, steel, copper alloys, glass, silicon, for example. The holes 5 are defined in the metal layer 123. Preferably the holes 5 are formed in the metal layer 23 by drilling or etching. The metal layer 123 has a planar profile.

The carrier 1 comprises a vacuum inlet 7 which is configured to be in fluid communication with the plurality of holes 5. Specifically the carrier 1 comprises a single vacuum chamber 12 which is in fluid communication with the holes 5 defined in the surface 3, and the vacuum inlet 7 is in fluid communication with said single vacuum chamber 12. In this example conduit columns 129, which are defined in a support layer 125 (which provides a mechanical support to the metal layer 123), provide for fluid communication between the single vacuum chamber 12 and the holes 5 defined in the surface 3. The vacuum inlet 7 can be selectively fluidly connected to a vacuum generator so that the vacuum generator can provide a vacuum at the plurality of holes 5 to hold components on the surface 3.

A check valve 17 is provided between an input 7a and an output 7b of vacuum inlet 7. The check valve 17 is operable to control the fluid flow (such as the flow of vacuum) from the vacuum inlet 7 into the single vacuum chamber 12, and is thus operable to control the fluid flow (such as the flow of vacuum) from the vacuum inlet 7 to the holes 5 in the surface 3. The check valve 17 comprises a biasing means in the form of a spring 16 which biases a plug member 18 towards plugging the output 7b of vacuum inlet 7. The plug member 18 is configured such that it will prevent fluid communication between the vacuum inlet 7 and the single vacuum chamber 12 when it plugs the output 7b of the vacuum inlet 7. The plug member 18 is movable, by providing a vacuum in the vacuum inlet 7, to become unplugged from the output 7b; unplugging the plug member 18 from the output 7b allows fluid communication between the vacuum inlet 7 and the single vacuum chamber 12 and holes 5 (e.g. allows a vacuum to flow from the vacuum inlet 7 into the single vacuum chamber 12 and holes 5).

In this embodiment the carrier 1 further comprises a second inlet 9 which can be selectively fluidly connected to another, second, vacuum generator, simultaneously when the first inlet 7 is fluidly connected to its respective vacuum generator. The other second inlet 9 is configured to be in fluid communication with the same holes 5 on the surface 3 of the carrier 1 as the holes 5 which the first inlet 7 is in fluid communication with. A second check valve 19 is provided between an input 9a and an output 9b of the second inlet 9. It will be understood that the second inlet is not essential for the present invention.

FIG. 2 provides a perspective view of a component handling assembly 20 according to an embodiment of the present invention. The component handling assembly 20 comprises a carrier 1 similar to the carrier 1 illustrated in FIG. 1. The assembly 20 is suitable for facilitating loading or unloading of components, such as components 50, onto/from the surface 3 of the carrier 1.

The component handling assembly 20 comprises a rotatable turret 80 which comprises a plurality of component handling heads 81. Each of the component handling heads 81 is configured to hold a component 50 by means of a vacuum. Each of the component handling heads 81 is configured such that it can move linearly with respect to the rotatable turret 80 so that the component handling head 81 can be selectively advanced in a direction towards the carrier 1 and/or away from the carrier 1 to load or unload an component 50 from the surface 3 of the carrier 1. A loading/unloading area 72 is provided in the assembly 20 where components 50 can be loaded onto the surface 3 by the component handling heads 81 on the turret 80.

FIG. 2 illustrates the carrier 1 located in a loading/unloading area 72; when the carrier 1 is located in the loading/unloading area 72 a component handling head 81 which holds an component 50, can be moved linearly towards the carrier 1 to place (load) the component 50 onto the surface 3 of the carrier 1, and/or, an empty component handling head 81 can be moved linearly towards the carrier 1 to pick (unload) an component 50 from the surface 3 of the carrier 1. Once a component 50 has been placed (loaded) and/or picked (unloaded) from the surface 3, the rotatable turret 80 is rotated so that the next component handling head 81 on the turret is moved into the loading/unloading area 72 where it can place another component 50 onto the surface 3 of the carrier or pick another component 50 from the surface 3 of the carrier 1; typically these steps are repeated until the carrier 1 is fully loaded with components 50 or until all component 50 have been unloaded from the surface 3 of the carrier 1.

The component handling assembly 20 further comprises: a vacuum generator 21, a vacuum sensor 22 (not shown in FIG. 2) and a controller 23. The vacuum generator 21 can be selectively arranged in fluid communication with said plurality of holes 5 in the surface 3 of the carrier 1 so that the vacuum generator can provide a vacuum at said plurality of holes 5 which is applied to components 50 supported on the surface 3 of the carrier 1 to hold the components 50 on the surface 3. The vacuum sensor 22 (not shown in FIG. 2) is arranged for sensing the level of vacuum applied to the component(s) 50 which are located on the surface 3 of the carrier 1. The controller 23 is configured to control the vacuum generator 21, based on the level of vacuum sensed by the vacuum sensor 22, so that a predefined level of vacuum is applied to components 50 located on the surface 3 during loading and/or unloading of components 50 onto/from the carrier 1. More specifically the controller 23 controls the vacuum generator 21 so that a substantially constant first predefined level of vacuum is applied to components 50 on the surface 3 of the carrier 1 when components 50 are being loaded onto the surface 3 of the carrier 1, and a substantially constant second predefined level of vacuum is applied to components 50 on the surface of the carrier when components 50 are being unloaded from the surface 3 of the carrier 1. In should be noted that in another embodiment a single predefined level of vacuum is applied to components supported on the surface during the loading and unloading of components from the carrier; in such an embodiment the controller 23 controls the vacuum generator 21 so that a substantially constant predefined level of vacuum is applied to components 50 on the surface 3 of the carrier 1 when components 50 are being loaded onto the surface 3 of the carrier 1, and so that the same substantially constant predefined level of vacuum is applied to components 50 on the surface of the carrier when components 50 are being unloaded from the surface 3 of the carrier 1.

In the example illustrated in FIG. 2 a conduit 25 is provided which fluidly connects the vacuum generator 21 with the inlet 7 of the carrier 1. Specifically the conduit 25 is fluidly connected to a channel (not shown) defined in a stage 75 on which the carrier 1 rests (in this example the stage 75 is defined by an x-y table 75). The channel extends through the stage 75 from the where the conduit 25 connects to the stage, to the surface 75a of the stage 75 to provide a channel opening on the surface 75a of the stage 75. The carrier 1 is arranged on the surface 75a of the stage 75 such that the inlet 7 on the carrier 1 is aligned with the channel opening, so that the inlet 7 is arranged in fluid communication with the channel and thus in fluid communication the conduit 25 and the vacuum generator 21 to which the conduit 25 is fluidly connected. In an alternative embodiment the conduit 25 may be connected directly to the inlet 7 of the carrier 1. It will be understood that inlet 7 may be selectively removed from the surface 75a of the stage 75 so that the vacuum generator 21 is no longer fluidly connected to the holes 5 in the surface 3 of the carrier 1.

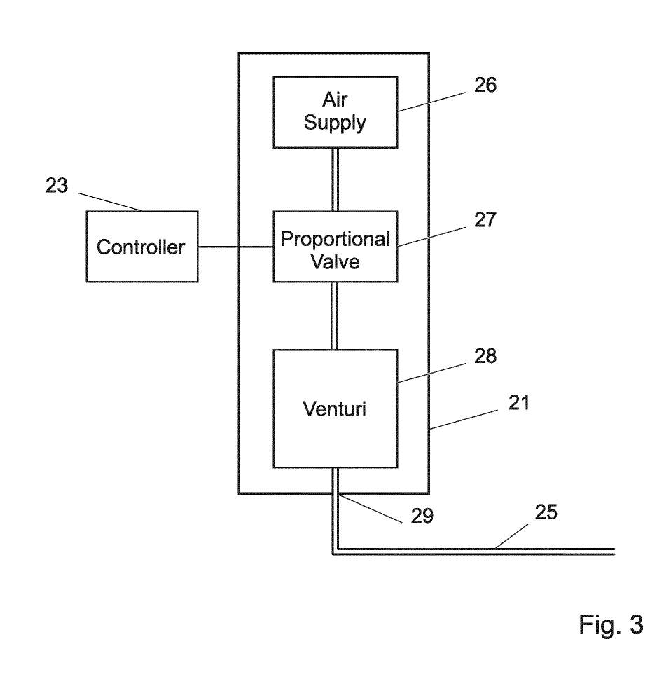

FIG. 3 is a block diagram illustrating in more detail the features of the vacuum generator 21. As shown in FIG. 3 the vacuum generator 21 comprises, a venturi 28; an air supply 26; and a proportional valve 27, which is arranged such that it can receive air from the air supply 26 and can input received air into the venturi 28. The venturi 28 generates a vacuum at its output 29 which is proportional to the pressure of the air input to the venturi 28. The proportional valve 27 is operable to control the pressure of air and flow? which is input to the venturi 28. The output 29 of the venturi 28 defines the output of the vacuum generator 21; thus the output 29 of the venturi 28 is fluidly connected to the inlet 7 of the carrier 1, via the conduit 25 when a vacuum is to be supplied to the holes 5 on the surface 3 of the carrier 1.

The venturi 28 is configured to generate a vacuum at its output which is directly proportional to the pressure of the air which is input to the venturi. So, for example the vacuum generated by the strength of the vacuum generator 21 may be doubled by doubling the pressure of the air input to the venturi 28.

The controller 23 is configured to control vacuum generated by the vacuum generator 21 by operating the proportional valve 7 to increase the pressure of air input to the venturi 28 to achieve an increase in the vacuum generated by the vacuum generator 21 and/or to decrease the pressure of the air input to the venturi 28 to achieve a decrease in the vacuum generated by the vacuum generator 21.

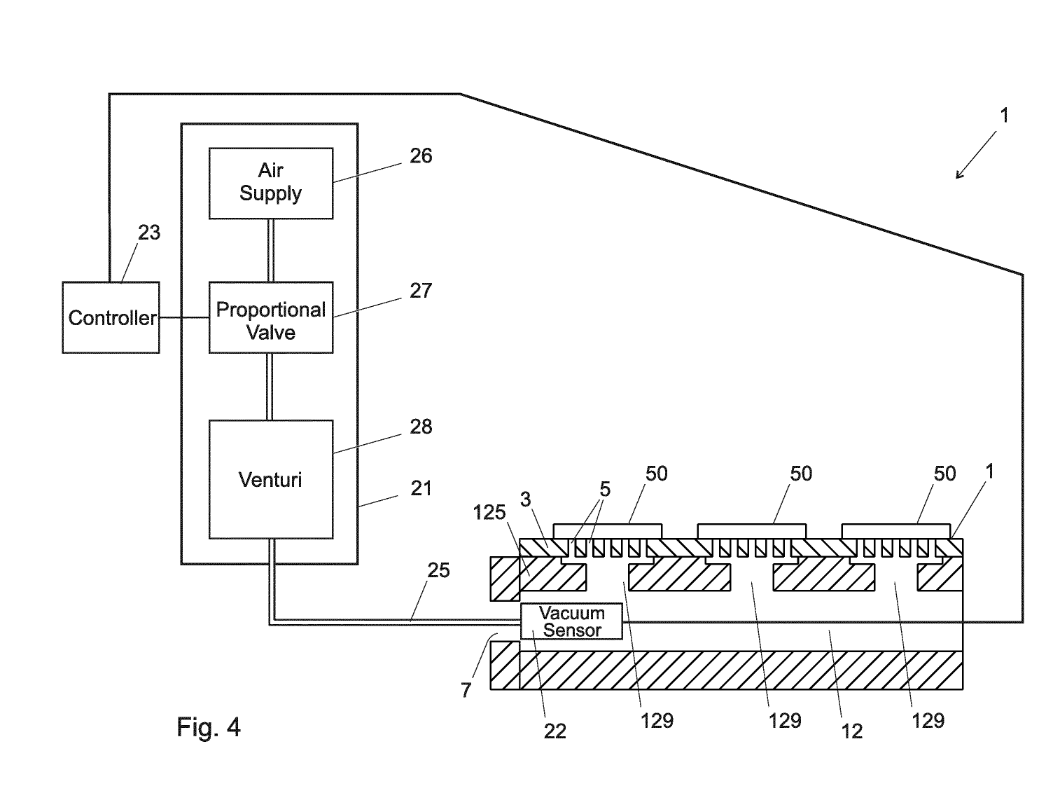

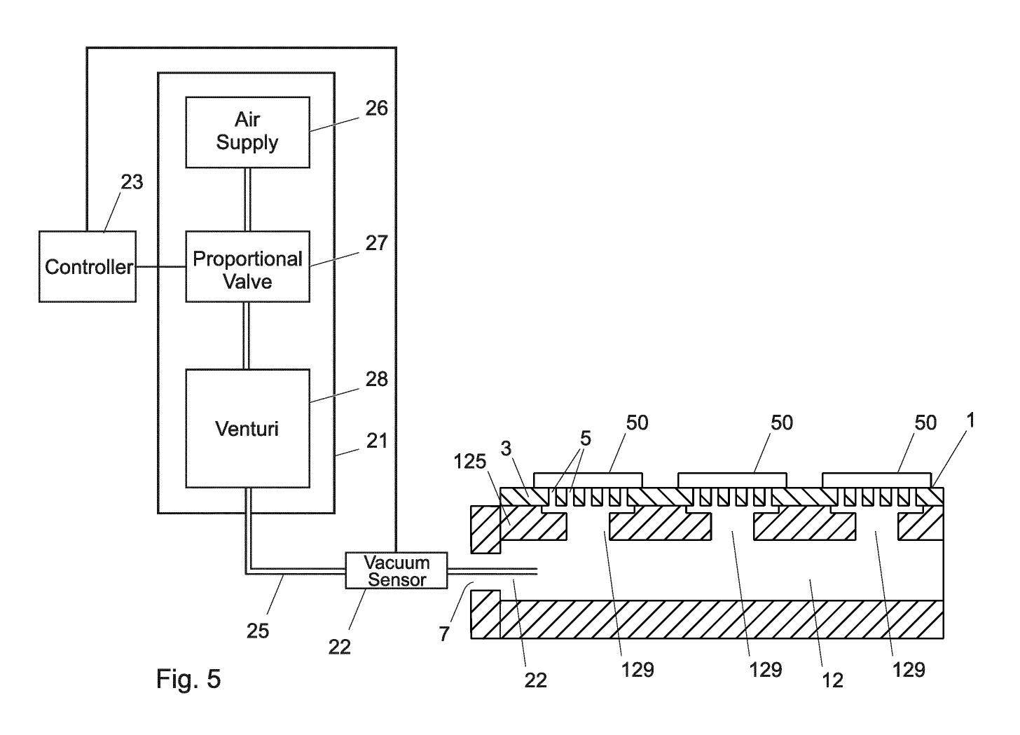

The vacuum sensor 22 provided in the component handling assembly 20, may be arranged in any suitable location within the assembly in which it can sense the level of vacuum applied to component(s) 50 which are located on the surface 3 of the carrier 1 (i.e. vacuum sensor 22 may be arranged in any suitable location within the assembly in which it can sense the level of vacuum force experienced by component(s) 50 which are located on the surface 3 of the carrier 1). FIGS. 3 and 4 illustrate two possible examples of where the vacuum sensor 22 could be positioned in the assembly 20.

FIG. 4 illustrates the vacuum sensor 22 located within the single vacuum chamber 12 of the carrier 1. In this position the vacuum sensor can sense the level of vacuum within the single vacuum chamber 12 of the carrier 1. The level of vacuum within the single vacuum chamber 12 of the carrier 1 is equivalent to the level of vacuum applied to components 50 which are located on the surface 3 of the carrier 1.

FIG. 5 illustrates the vacuum sensor 22 located within the conduit 25; specifically the vacuum sensor 22 is located proximate to the end of the conduit 25 which is connected to the inlet 7 of the carrier 1. The level of vacuum in this region of the conduit 25 is equivalent to the level of vacuum in the single vacuum chamber 12 of the carrier 1 and is thus also equivalent to the level of vacuum applied to components 50 which are located on the surface 3 of the carrier 1. Most preferably the vacuum sensor 22 will be located in the conduit 25 but adjacent to the single vacuum chamber 12.

As mentioned the controller 23 controls the vacuum generator 21 so that a substantially constant first predefined level of vacuum is applied to components 50 on the surface 3 of the carrier 1 when components 50 are being loaded onto the surface 3 of the carrier 1, and a substantially constant second predefined level of vacuum is applied to components 50 on the surface of the carrier when components 50 are being unloaded from the surface 3 of the carrier 1. This will ensure that components 50 supported on the surface 3 of a carrier 1, experience a first substantially constant vacuum force during consecutive loading of a plurality of components 50 onto the surface 3 of the carrier 1; and that components 50 supported on the surface 3 of the carrier 1 experience a second substantially constant vacuum force during consecutive unloading of a plurality of components 50 from the surface 3 of the carrier 1. In this embodiment the first predefined level of vacuum is greater than the second predefined level of vacuum.

The controller 23 decreases the vacuum generated by the vacuum generator 21 when an additional component 50 is loaded onto the surface 3 of the carrier 1, so that the first predefined level of vacuum is applied to components 50 supported on the surface 3 when the additional component is loaded onto the surface 3 of the carrier 1. In order to decrease the vacuum generated by the vacuum generator 21 the controller 23 adjusts the proportional valve 7 to decrease the pressure of the air input to the venturi 28; decreasing the pressure of the air input to the venturi 28 decreases the vacuum generated by the venturi 28. The controller 23 decreases the pressure of the air input to the venturi 28 by an amount which is directly proportional to the amount by which the vacuum generated by the vacuum generator 21 is to be decreased.

The controller 23 increases the vacuum generated by the vacuum generator 21 when a component is unloaded (i.e. picked) from the surface 3 of the carrier 1, so that the second predefined level of vacuum is applied to components 50 remaining supported on the surface 3 of the carrier 1 when a component is unloaded from the surface 3 of the carrier 1. In order to increase the vacuum generated by the vacuum generator 21 the controller 23 adjusts the proportional valve 7 to increase the pressure of air input to the venturi 28; increasing the pressure of the air input to the venturi 28 increases the vacuum generated by the venturi 28. The controller 23 increases the pressure of the air input to the venturi 28 by an amount which is directly proportional to the amount by which the vacuum generated by the vacuum generator 21 is to be increased.

Preferably the first predefined level of vacuum is greater than the level of vacuum which is applied by a component handling head 81 to a component 50 to hold a component 50 on a component handling head 81; advantageously this will facilitate the transfer of the components 50 from the component handling heads 81 to the surface 3 of the carrier 1 during loading. Preferably the second predefined level of vacuum is less than the level of vacuum which is applied by a component handling head 81 to a component 50 to hold component 50 on a component handling head 81; advantageously this will enable components 50 to be picked (unloaded) directly from the surface 3 of the carrier 1 using exclusively the component handling heads 81 on the turret.

During use an empty carrier 1 is provided on the stage 75 (e.g. x-y table 75) so that the inlet 7 on the carrier 1 is fluidly connected to the channel defined in the stage 75. The stage 75 is then moved to transport the carrier to the loading/unloading area 72 where components 50 (such as electronic components) can be loaded onto the surface 3 by the component handling heads 81 on the turret.

The vacuum generator 21 is then operated to provide a first predefined level of vacuum in the single vacuum chamber 12 and/or conduit 25; the first predefined level of vacuum corresponds to the first predefined level of vacuum which is to be applied to components 50 on the surface 3 of the carrier 1 are to experience during loading. This can be achieved by adjusting the vacuum generator 21 until the vacuum sensor 22 in the single vacuum chamber 12 or conduit 25 measures a level of vacuum equal to the first predefined level of vacuum; more specifically the proportional valve 27 is adjusted to provide the necessary air pressure input to the venturi 28 to causes the venturi 28 to generate a vacuum sufficient to create a level of vacuum in the single vacuum chamber 12 which is equal to the first predefined level of vacuum.

Once the level of vacuum in the single vacuum chamber 12 which is equal to the first predefined level of vacuum, a component 50 is then loaded onto the surface 3 of the carrier 1 by a component handling head 81 on the turret. When a component 50 is loaded onto the surface 3 of the carrier 1 it will cover one or more holes 5 on the surface 3 of the carrier 1, thereby reducing, or completely blocking, fluid flow through those one or more holes 5. Consequently, loading an component 50 onto the surface 3 increases the level of vacuum in the single vacuum chamber 12 and/or conduit 25 and thus increases the level of vacuum applied to any components 50 which are located on the surface 3 of the carrier 1.

The increase in the level of vacuum in the single vacuum chamber 12 and/or conduit 25 is sensed by the vacuum sensor 22. When the vacuum sensor 22 senses an increase in level of vacuum in the single vacuum chamber 12 and/or conduit 25, which occurs when a component 50 is loaded onto the surface 3 of the carrier 1, the controller 23 operates the proportional valve 27 in the vacuum generator 21, to decrease the pressure of the air input to the venturi 28 so as to achieve a decrease in the vacuum generated by the vacuum generator 21, so that the level of vacuum in the single vacuum chamber 12 and/or conduit 25 is brought back to a level which is equal to the first predefined level of vacuum; this ensures that the first predefined level of vacuum is applied to components 50 on the surface 3 of the carrier 1 even when the additional component 50 has been loaded onto the surface 3.

For example, the first predefined level of vacuum may be defined to be 20 kPa; the vacuum generator 21 is adjusted by the controller 23 so that it provides a vacuum of 20 kPa in the single vacuum chamber 12 or conduit 25 (i.e. the controller 23 adjusts the proportional valve 27 so that the pressure of the air input to the venturi 28 the until the vacuum sensor 22 measures a level of vacuum of 20 kPa in the single vacuum chamber 12 and/or conduit 25, depending on where the vacuum sensor 22 is located).

Next a component 50 is loaded onto the surface 3 of the carrier 1 by the component handling head 81 on the turret. The component handling head 81 on the turret holds the component 50 by means of a level of vacuum, such as 15 kPa for example, which less than the first predefined level of vacuum, so that when the component 50 is moved onto the surface 3 of the carrier 1 by the component handling head 81, the level of vacuum pulling the component 50 towards the surface 3 will be greater than the level of vacuum holding the component 50 on the component handling head 81. This facilitates the transfer of the component 50 from the component handling head 81 onto the surface 3 of the carrier 1.

Optionally the assembly 20 may comprise a means for selecting a map, from a plurality of predefined maps, indicating locations on the surface 3 of the carrier 1 where components are to be loaded, and a means for moving the carrier 1 relative to the component handling heads 81 on the turret 80 so that consecutive component handling heads 81 can place the components 50 on the surface 3 of the carrier at the locations shown in the selected map. Furthermore, optionally, the assembly 20 may further comprise a means for aligning a component 50 to a predefined orientation, while the component 50 is held by the component handling head 81 prior to loading that component 50 onto the surface 3 of the carrier 1 so that the component 50 has a predefined orientation when supported on the surface 3.

When the component 50 has been loaded onto the surface 3 of the carrier 1 it will overlay one or more holes 5 on the surface 3 thereby reducing, or completely blocking, fluid flow through those one or more holes 5 causing an increase of 1 kPa in the vacuum in the single vacuum chamber 12 and/or conduit 25. Thus the level of vacuum within the single vacuum chamber 12 and/or conduit 25 will increase to 21 kPa when the component 50 is loaded onto the surface 3 of the carrier 1. The vacuum sensor 22 senses the increase in level of vacuum within the single vacuum chamber 12 and/or conduit 25. In response to the increase in level of vacuum sensed by the vacuum sensor 22, the controller 23 adjusts the vacuum generator 21 so as to decrease the vacuum generated by vacuum generator 21 by an amount sufficient to reduce the level of vacuum in the single vacuum chamber 12 and/or conduit 25 to the first predefined level of vacuum of 20 kPa again. Specifically, in this example, the controller 23 controls the proportional valve 27 to decrease the pressure of the air input to the venturi 28 by 1 kPa so as to decrease the vacuum generated by the vacuum generator 23 by an 1 kPa so as to return the level of vacuum within the single vacuum chamber 12 and/or conduit 25 back to the first predefined level of vacuum of 20 kPa. These steps are repeated for each additional component 50 which is loaded onto the surface 3 of the carrier 1 so that the components 50 supported on the surface 3 of the carrier 1 experience a substantially constant vacuum force of 20 kPa even as additional components 50 are loaded onto the surface 3 of the carrier 1. For each additional component which is loaded onto the surface 3 of the carrier 1 the controller 23 adjusts the proportional valve to decrease the pressure of the air input to the venturi 28 by an amount sufficient to maintain a substantially constant level of vacuum of 20 kPa within the vacuum chamber 12 and/or conduit 25.

After the carrier 1 has been fully loaded with components 50, the carrier 1 is moved to a testing area or processing area where the components 50 are tested or processed. Following testing or processing the carrier 1 is moved a back to the loading/unloading area 72 where the tested/processed components 50 can be picked from the surface 3 of the carrier 1 by the component handling heads 81 on the turret.

After the carrier 1 has been moved back into loading/unloading area 72 after testing/processing, and prior to unloading the tested/processed components 50 from the surface 3 of the carrier 1, the controller 23 first adjusts the vacuum generator 21 so that a second predefined level of vacuum is applied to the components 50 on the surface 3 of the carrier 1. The second predefined level of vacuum is preferably less than the level of vacuum which a component handling head 81 on the turret applies to an component 50 to hold that component 50. In this example the second predefined level of vacuum is 12 kPa; accordingly after the carrier 1 has been moved into loading/unloading area 72 and prior to unloading the tested/processed components 50 from the surface 3 of the carrier 1, the controller 23 adjusts the vacuum generator 21 so that it provides a level of vacuum of 12 kPa in the single vacuum chamber 12 and/or conduit 25 (i.e. the controller 23 adjusts the proportional valve to decrease the pressure of the air input to the venturi 28 to reduce the level of vacuum in the single vacuum chamber 12 and/or conduit to 12 kPa i.e. until the vacuum sensor 22 measures a level of vacuum of 12 kPa in the single vacuum chamber 12 and/or conduit 25, depending on where the vacuum sensor 22 is located).

Next a component 50 is picked (i.e. unloaded) from the surface 3 of the carrier 1 by the component handling head 81 on the turret. When a component 50 is picked (i.e. unloaded) from the surface 3 of the carrier 1, fluid can again flow through the one or more holes 5 which that component 50 had overlayed. Consequently, unloading a component 50 decreases the level of vacuum in the single vacuum chamber 12 and/or conduit 25 and thus decreases the level of vacuum applied to components 50 remaining on the surface 3 of the carrier 1.

For example unloading a component 50 from the surface 3 of the carrier 1 decreases the level of vacuum in the single vacuum chamber 12 and/or conduit 25 from the second predefined level of vacuum 12 kPa to 11 kPa. The vacuum sensor 22 senses this decrease in level of vacuum within the single vacuum chamber 12 and/or conduit 25. In response to the decrease in level of vacuum sensed by the vacuum sensor 22, the controller 23 adjusts the vacuum generator 21 so as to increase the vacuum generated by the vacuum generator 21 by an amount sufficient to increase the level of vacuum in the single vacuum chamber 12 and/or conduit 25 to the second predefined level of vacuum of 12 kPa again. Specifically when the vacuum sensor 22 senses that the level of vacuum within the single vacuum chamber 12 and/or conduit 25 has decreased from the second predefined level of vacuum 12 kPa to 11 kPa (i.e. below the second predefined level of vacuum) the controller 23 controls the proportional valve 27 to increase the pressure of the air input to the venturi 28 so as to increase the vacuum generated by the vacuum generator 21 by an amount sufficient to return the level of vacuum within the single vacuum chamber 12 and/or conduit 25 back to the second predefined level of vacuum of 12 kPa. These steps are repeated for each additional component 50 which is unloaded from the surface 3 of the carrier 1 so that a substantially constant vacuum of 12 kPa is applied to components 50 supported on the surface 3 of the carrier 1 even as additional components 50 are unloaded from the surface 3 of the carrier 1. For each additional component which is unloaded from the surface 3 of the carrier 1 the controller 23 adjusts the proportional valve to increase the pressure of the air input to the venturi 28 by an amount sufficient to maintain a substantially constant level of vacuum of 12 kPa within the vacuum chamber 12 and/or conduit 25.

Since the component handling head 81 on the turret holds the component with a level of vacuum of 15 kPa which is greater than the second predefined level of vacuum of 12 kPa which is applied to components 50 on the surface 3 of the carrier 1 during unloading, when the component handling head 81 is moved close to a component 50 which is to be unloaded, the 15 kPa vacuum pulling the component 50 onto the component carrier head 81 will be overcome the 12 kPa vacuum holding the component 50 on the surface 3 of the carrier 1, thereby facilitating the transfer of the component 50 from the surface 3 of the carrier 1 onto the component carrier head 81. Advantageously this allows components 50 to be unloaded (picked) from the surface 3 of the carrier 1 using exclusively the component carrier heads 81 on the turret.

In the above described example the tested/processed components are exclusively unloaded from the carrier (i.e. a plurality of tested/processed components are consecutively unloaded from the carrier without loading a component onto the carrier). However in a further embodiment alternating loading and unloading of singular components takes placed, whereby a single component (e.g. a tested/processed component) is unloaded from the carrier to leave a vacant area on the surface, and another component (e.g. a component which is to be tested/processed) is placed in the vacant area prior to picking the next component from the carrier etc.:

In this embodiment a carrier having tested/processed components supported on its surface 3 is moved into the loading/unloading area 72. The controller 23 adjusts the vacuum generator so that a third predefined level of vacuum is applied to the tested/processed components supported on its surface 3. This can be achieved by adjusting the vacuum generator 21 until the vacuum sensor 22 in the single vacuum chamber 12 and/or conduit 25 measures a level of vacuum equal to the third predefined level of vacuum; more specifically the controller 23 adjusts the proportional valve 27 to provide the necessary air pressure input to the venturi 28 to causes the venturi 28 to generate a vacuum sufficient to create a level of vacuum in the single vacuum chamber 12 and/or conduit 25 which is equal to the third predefined level of vacuum. The third predefined level of vacuum is greater than the second predefined level of vacuum and less than the first predefined level of vacuum (and is also less than the level of vacuum which a component handling head 81 applies to a component 50 to hold a component 50). In this example the third predefined level of vacuum is 16 kPa (which is less than the first predefined level of vacuum of 20 kPa, and is less than the level of vacuum 15 kPa which a component handling head 81 applies to a component 50 to hold the component 50, and is also greater than the second predefined level of vacuum of 12 kPa).

In the present embodiment a first component handling head 81 on the turret 80 is empty so that it can be used to unload a first tested/processed component from the surface 3 of the carrier; all other component handling heads 81 on the turret 80 hold a respective component 50 (which are due to be tested/processed) which are to be loaded onto the surface 3 of the carrier 1.

Next a first tested/processed component 50 is picked (i.e. unloaded) from the surface 3 of the carrier 1 by the first component handling head 81 on the turret 80. When the first tested/processed component 50 has been unloaded from the surface 3 of the carrier 1 by the first component handling head 81, a vacant area on the surface 3 is provided which can receive a component 50.

The rotatable turret 80 is then rotated so that the next component handling head 81 on the turret is moved into the loading/unloading area 72 where it can load the component 50 which it holds (i.e. a component which is due to be tested/processed) onto vacant area on the surface 3 of the carrier 1.

The component handling head 81 is advanced towards the surface 3 of the carrier 1 and loads the component 50 which it holds onto vacant area on the surface 3 of the carrier 1, so that the vacant area now becomes occupied by the component 50. Once the component handling head 81 loads the component 50 into the vacant area, it is then moved by the turret to a position where it can pick (unload) a tested/processed component which is located adjacent to the component 50 which was loaded into the vacant area. The component handling head 81 picks (unloads) the adjacent tested/processed component and is then retracted away from the surface of the carrier 1. When the adjacent tested/processed component 50 has been unloaded from the surface 3 of the carrier 1 by the component handling head 81, a second vacant area on the surface 3 is provided which can receive a component 50.

When the tested/processed component 50 is picked (i.e. unloaded) from the surface 3 of the carrier 1, fluid can again flow through the one or more holes 5 which that component 50 had overlayed. Consequently, unloading a tested/processed component 50 decreases the level of vacuum in the single vacuum chamber 12 and/or conduit 25 and thus decreases the level of vacuum applied to components 50 remaining on the surface 3 of the carrier 1. In this example unloading a tested/processed component 50 from the surface 3 of the carrier 1 decreases the level of vacuum in the single vacuum chamber 12 and/or conduit 25 from the third predefined level of vacuum 14 kPa to 13 kPa. The vacuum sensor 22 senses this decrease in level of vacuum within the single vacuum chamber 12 and/or conduit 25. In response to the decrease in level of vacuum sensed by the vacuum sensor 22, the controller 23 adjusts the vacuum generator 21 so as to increase the vacuum generated by the vacuum generator 21 by an amount sufficient to increase the level of vacuum in the single vacuum chamber 12 and/or conduit 25 to the third predefined level of vacuum of 14 kPa again. Specifically when the vacuum sensor 22 senses that the level of vacuum within the single vacuum chamber 12 and/or conduit 25 has decreased from the third predefined level of vacuum 14 kPa to 13 kPa (i.e below the third predefined level of vacuum) the controller 23 controls the proportional valve 27 to increase the pressure of the air input to the venturi 28 so as to increase the vacuum generated by the vacuum generator 21 by an amount sufficient to return the level of vacuum within the single vacuum chamber 12 and/or conduit 25 back to the third predefined level of vacuum of 14 kPa.

The rotatable turret 80 is then rotated so that the next component handling head 81 on the turret is moved into the loading/unloading area 72 where it can load the component 50 which it holds ((i.e. a component which is due to be tested/processed) onto the second vacant area on the surface 3 of the carrier 1.

The component handling head 81 is then advanced towards the surface 3 of the carrier 1 and loads the component 50 which it holds onto the second vacant area on the surface 3 of the carrier 1, so that the second vacant area now becomes occupied by the component 50.

When the component 50 has been loaded onto the surface 3 of the carrier 1 it will overlay one or more holes 5 on the surface 3 thereby reducing, or completely blocking, fluid flow through those one or more holes 5 causing an increase in the level of vacuum in the single vacuum chamber 12 and/or conduit 25. In this example loading a component on the surface 3 of the carrier 1 increase the level of vacuum in the single vacuum chamber 12 and/or conduit 25 by 1 kPa. Thus the level of vacuum within the single vacuum chamber 12 and/or conduit 25 will increase to 15 kPa when the component 50 is loaded onto the second vacant area on surface 3 of the carrier 1. The vacuum sensor 22 senses the increase in level of vacuum within the single vacuum chamber 12 and/or conduit 25. In response to the increase in level of vacuum sensed by the vacuum sensor 22, the controller 23 adjusts the vacuum generator 21 so as to decrease the vacuum generated by vacuum generator 21 by an amount sufficient to reduce the level of vacuum in the single vacuum chamber 12 and/or conduit 25 to the third predefined level of vacuum of 14 kPa again. Specifically, in this example, the controller 23 controls the proportional valve 27 to decrease the pressure of the air input to the venturi 28 by 1 kPa so as to decrease the vacuum generated by the vacuum generator 23 by an 1 kPa so as to return the level of vacuum within the single vacuum chamber 12 and/or conduit 25 back to the third predefined level of vacuum of 14 kPa.

These steps are repeated for each tested/processed component which is unloaded from the surface of the carrier and for each component which is loaded onto the carrier, until all tested/processed component 50 have been unloaded from the surface 3 of the carrier 1 and the surface of the carrier 1 has been fully loaded with components 50 which are due to be tested/processed. Importantly the controller 23 controls the vacuum generator 21 to alternatively increase and decrease the vacuum generated by the vacuum generator 21 as components are alternately unloaded and loaded onto the surface 3 of the carrier 1, so that a substantially constant third predefined level of vacuum of 14 kPa is applied to components 50 on the surface 3 of the carrier 1.

Advantageously, in this embodiment the component handling heads 81 on the turret 80 both load a component and unload a component before they are retraced away from the surface 3 of the carrier 1; this provides for a faster and more efficient component handling. Moreover a substantially constant third predefined level of vacuum of 14 kPa is applied to components 50 on the surface 3 of the carrier 1 even as components 50 are alternately loaded onto and unloaded from the surface 3 of the carrier. Furthermore since the third predefined level of vacuum of 14 kPa is less than the first predefined level of vacuum of 20 kPa (and less than the level of vacuum 15 kPa which a component handling head 81 applies to a component 50 to hold the component 50) and greater than the second predefined level of vacuum of 12 kPa, the third predefined level of vacuum is therefore strong enough to reliably hold components 50 on the surface 3 of the carrier 1 while still being low enough to allow exclusive unloading of the components by the component handling heads 81.

Various modifications and variations to the described embodiments of the invention will be apparent to those skilled in the art without departing from the scope of the invention as defined in the appended claims. Although the invention has been described in connection with specific preferred embodiments, it should be understood that the invention as claimed should not be unduly limited to such specific embodiment.

1. A component handling assembly suitable for facilitating loading or unloading a plurality of components onto/from a carrier, the assembly comprising,
a carrier which comprises a surface on which a plurality of components can be supported, wherein the surface has a plurality of holes defined therein;
a vacuum generator which can be arranged in fluid communication with said plurality of holes in the surface of the carrier so that a vacuum can be applied, through said plurality of holes, to components supported on the surface of the carrier, to hold components on the surface of the carrier;
a vacuum sensor for sensing the level of vacuum applied to components supported on the surface of the carrier;
a controller for controlling the vacuum generator during loading and/or unloading of component(s) onto/from the surface of the carrier, based on the vacuum sensed by the vacuum sensor, so that a predefined level of vacuum is applied to component(s) supported on the surface during loading and/or unloading of component(s) onto/from the carrier.

2. An assembly according to claim 1 wherein the controller is configured for controlling the vacuum generator during loading and/or unloading of component(s) onto/from the surface of the carrier, based on the vacuum sensed by the vacuum sensor, so that the a single predefined level of vacuum is applied to components supported on the surface during the loading and unloading of components from the carrier.

3. An assembly according to claim 1 wherein the controller is configured to control the vacuum generated by the vacuum generating means, based on the level of vacuum sensed by the vacuum sensor, so that,
a first predefined level of vacuum is applied to components supported on the surface during loading of component(s) onto the surface of the carrier;
a second predefined level of vacuum is applied to components supported on the surface during unloading of component(s) from the surface of the carrier.

4. A assembly according to claim 1 wherein the controller is configured to control the vacuum generated by the vacuum generating means, based on the level of vacuum sensed by the vacuum sensor, so that,
a third predefined level of vacuum is applied to components supported on the surface during simultaneous loading of components onto the surface of the carrier and unloading of component(s) from the surface of the carrier.

5. An assembly according to claim 1 wherein the controller is configured to decrease the vacuum generated by the vacuum generator when a component is loaded onto the surface of the carrier, so that said predefined level of vacuum is applied to component(s) supported on the surface of the carrier.

6. An assembly according to claim 1 wherein the controller is configured to increase the vacuum generated by the vacuum generator when a component is unloaded from the surface of the carrier, so that said predefined level of vacuum is applied to component(s) remaining supported on the surface of the carrier.

7. An assembly according to claim 1 wherein the vacuum generator comprises,
a venturi, an output of which can be fluidly connected to the holes on the surface of the carrier;
an air supply which can input air to the venturi to generate a vacuum at the output of the venturi; and
a proportional valve, which is arranged such that it can control the flow of air between the air supply and venturi, so that the proportional valve is operable to control the pressure of air which is input to the venturi; and
wherein said controller is configured to control the vacuum generator so that a predefined level of vacuum is applied to components on the carrier, by operating the proportional valve to increase the pressure of air input to the venturi to achieve an increase in the vacuum generated by the vacuum generator, and/or, to decrease the pressure of the air input to the venturi to achieve a decrease in the vacuum generated by the vacuum generator.

8. An assembly according to claim 1 wherein the system further comprises,
a conduit which is fixed to an output of the vacuum generator, and wherein the vacuum sensor is located within the conduit, and/or
a single vacuum chamber which is fluidly connected to the plurality of holes on the surface of the carrier, and wherein the vacuum sensor is located within said single vacuum chamber.

9. An assembly according to claim 1 wherein the assembly further comprises one or more component handling heads which can be used to load and/or unload components onto/from the surface of a carrier, and wherein each of the one or more component handling heads is configured such that it can hold a component by means of a vacuum, and,
wherein the predefined level of vacuum is less than the level of vacuum which is used to hold a component on a component handling head, so that components can be unloaded from the carrier using the one or more component handling heads exclusively.

10. A method of loading or unloading components from a surface of a carrier, the method comprising the steps of,
receiving into a loading or unloading area, a carrier which comprises surface on which the plurality of components can be supported, wherein the surface has a plurality of holes defined therein;
using a vacuum generator to provide a vacuum through said plurality of holes, which can be applied, through said plurality of holes, to components supported on the surface of the carrier;
using a vacuum sensor to sense the level of vacuum applied to component(s) supported on the surface of the carrier;
using a controller to control the vacuum generator during loading and/or unloading of component(s) onto/from the surface of the carrier, based on the level of vacuum sensed by the vacuum sensor, so that a predefined level of vacuum is applied component(s) supported on the surface during loading and/or unloading component(s) onto/from the surface of the carrier.

11. A method according to claim 10 comprising the step(s) of,
controlling the vacuum generated by the vacuum generator, based on the level of vacuum sensed by the vacuum sensor, so that a first predefined level of vacuum is applied to component(s) supported on the surface during loading of component(s) onto the surface of the carrier; and/or
controlling the vacuum generated by the vacuum generator, based on the level of vacuum sensed by the vacuum sensor, so that a second predefined level of vacuum is applied to component(s) supported on the surface during unloading of component(s) from the surface of the carrier, and/or
controlling the vacuum generated by the vacuum generator, based on the level of vacuum sensed by the vacuum sensor, so that a third predefined level of vacuum is applied to component(s) supported on the surface during simultaneous loading of component(s) onto the surface of the carrier and unloading of component(s) from the surface of the carrier.

12. A method according to claim 10, comprising the step of,
decreasing the vacuum generated by the vacuum generator when a component is loaded onto the surface of the carrier, so that a first predefined level of vacuum is applied to component(s) supported on the surface of the carrier.

13. A method according to claim 11, comprising the step of,
increasing the vacuum generated by the vacuum generator when a component is unloaded from the surface of the carrier, so that a second predefined level of vacuum is applied to component(s) remaining supported on the surface of the carrier.

14. A method according to claim 11, wherein the vacuum generator comprises, a venturi, an output of which can be fluidly connected to the holes on the surface of the carrier; an air supply which can input air to the venturi to generate a vacuum at the output of the venturi; and a proportional valve, which is arranged such that it can control the flow of air between the air supply and venturi, so that the proportional valve is operable to control the pressure of air which is input to the venturi; and
wherein the step of using a controller to control the vacuum generator so that a predefined level of vacuum is applied to component(s) on the surface of the carrier comprises,
using the controller to operate the proportional valve to increase the pressure of air input to the venturi to increase the vacuum generated by the vacuum generator and/or using the controller to operate the proportional valve to decrease the pressure of the air input to the venturi to decrease in the vacuum generated by the vacuum generating means.
